(19) United States
(12) Patent Application Publication
(10) Pub. No.: US 2026/0299433 A1
(43) Pub. Date: Oct. 1, 2026

(54) DIGITAL LITHOGRAPHY EXPOSURE UNIT BOUNDARY SMOOTHING

(71) Applicant: APPLIED MATERIALS, INC., Santa Clara, CA (US)

(72) Inventor: Chi-Ming Tsai, San Jose, CA (US)

(21) Appl. No.: 19/160,716

(22) PCT Filed: Mar. 4, 2024
(86) PCT No.: PCT/US2024/018409

§ 371 Date: Aug. 28, 2025

Related U.S. Application Data
(60) Provisional application No. 63/488,713, filed on Mar. 6, 2023.
(60) Provisional application No. 63/615,596, filed on Dec. 28, 2023.

(51) Int. Cl. G03F 7/00; G03F 7/20

(52) U.S. Cl. CPC G03F 7/70558; G03F 7/2057; G03F 7/70291; G03F 7/70725

(57) ABSTRACT

A system includes a memory and at least one processing device, operatively coupled to the memory, to perform operations including initiating a digital lithography process to use a digital lithography system to pattern a substrate, controlling an area ratio in a first direction with respect to a first pair of adjacent exposure units of the digital lithography system, and controlling a dose ratio in a second direction perpendicular to the first direction with respect to a second pair of adjacent exposure units of the digital lithography system.

### TECHNICAL FIELD

The instant specification generally relates to electronic device fabrication. More specifically, the instant specification relates to digital lithography.

### BACKGROUND

Photolithography is used in the manufacturing of semiconductor devices and display devices, such as flat panel display devices. Generally, flat panel displays include a layer of liquid crystal material as a phase change material at each pixel, sandwiched between two plates. Examples of flat panel display devices include thin-film display devices, such as, e.g., liquid crystal display (LCD) devices and organic light emitting diode (OLED) display devices. For example, flat panel display devices can be used with computers, touch panel devices, personal digital assistants (PDAs), cell phones, television monitors, etc. When power from a power supply is applied across or through the liquid crystal material, an amount of light passing through the liquid crystal material is controlled, e.g., selectively modulated, at the pixel locations enabling images to be generated on the display. In some instances, large-area substrates can be used to manufacture flat panel display devices.

### SUMMARY

The following is a simplified summary of the disclosure in order to provide a basic understanding of some aspects of the disclosure. This summary is not an extensive overview of the disclosure. It is intended to neither identify key or critical elements of the disclosure, nor delineate any scope of the particular implementations of the disclosure or any scope of the claims. Its sole purpose is to present some concepts of the disclosure in a simplified form as a prelude to the more detailed description that is presented later.

In accordance with an embodiment, a is provided. The system includes a memory and at least one processing device, operatively coupled to the memory, to perform operations including initiating a digital lithography process to use a digital lithography system to pattern a substrate, controlling an area ratio in a first direction with respect to a first pair of adjacent exposure units of the digital lithography system, and controlling a dose ratio in a second direction perpendicular to the first direction with respect to a second pair of adjacent exposure units of the digital lithography system.

In accordance with another embodiment, a method is provided. The method includes initiating, by at least one processing device, a digital lithography process to use a digital lithography system to pattern a substrate, controlling, by the at least one processing device, an area ratio in a first direction with respect to a first pair of adjacent exposure units of the digital lithography system, and controlling, by the at least one processing device, a dose ratio in a second direction perpendicular to the first direction with respect to a second pair of adjacent exposure units of the digital lithography system.

In accordance with another embodiment, a system is provided. The system includes a stage associated with a plurality of scan regions, a plurality of exposure units located above the stage, the plurality of exposure units including a first pair of adjacent exposure units and a second pair of adjacent exposure units, and at least one processing device, operatively coupled to a memory, to perform operations including initiating a digital lithography process to pattern a substrate disposed on the stage, controlling an area ratio in a first direction with respect to the first pair of adjacent exposure units, and controlling a dose ratio in a second direction perpendicular to the first direction with respect to the second pair of adjacent exposure units.

### BRIEF DESCRIPTION OF THE DRAWINGS

Aspects and implementations of the present disclosure will be understood more fully from the detailed description given below and from the accompanying drawings, which are intended to illustrate aspects and implementations by way of example and not limitation.

FIG. 1 is a schematic partial perspective view of a digital lithography system, in accordance with some embodiments.

FIG. 2 is a block diagram of a digital lithography system, in accordance with some embodiments.

FIG. 3 is a diagram of a digital lithography system, in accordance with some embodiments.

FIG. 4 is a top-down view of a digital lithography system, in accordance with some embodiments.

FIGS. 5A-5D are top-down views showing a scan path of a substrate through a single digital lithography exposure unit of a digital lithography system, in accordance with some embodiments.

FIG. 6 is a diagram illustrating exposure unit boundary smoothing performed by a digital lithography system from a top-down view, in accordance with some embodiments.

FIG. 7 is a flow chart of a method for implementing digital lithography exposure unit boundary smoothing, in accordance with some embodiments.

FIG. 8 is a block diagram illustrating a computer system, according to certain embodiments.

### DETAILED DESCRIPTION

Digital lithography, also referred to as maskless or direct write lithography, refers to processes that use a digital pattern file to cause electromagnetic radiation, such as laser light, ultraviolet light (UV), near-UV, etc., to expose a photoresist to create patterns on a substrate without requiring the use of a photomask. Examples of digital lithography include maskless lithography, direct-write lithography, etc. Digital lithography technology enables high speed and high-resolution maskless lithography solutions for printed circuit board (PCB) patterning, solder masks, flat panel displays, laser marking, and other digital exposure systems that benefit from high speed and precision. Digital lithography can be used to directly expose patterns onto photoresist films without the use of contact masks (e.g., photomasks). This can reduce material cost, improves production rates, and allow for rapid changes of the pattern. Direct exposure increases productivity compared to narrow laser beam or masked systems. An advantage of digital lithography is the ability to change lithography patterns from one run to the next, without incurring the cost of generating a new photomask. Illustratively, digital lithography can be used to perform large-area patterning during electronic device fabrication.

A digital lithography system can include multiple image projection systems or digital lithography exposure units (“exposure units”), also referred to herein as EYEs. A set of exposure units can be attached to a respective bridge, and a digital lithography system can include one or more bridges. Some digital lithography systems can perform stitching to fabricate flat panel display devices from large area substrates. During stitching, each exposure unit can be responsible for a portion of a printing area to increase throughput. For example, some exposure units can print or expose a rectangular non-overlapping region, or clipping layer. Each of the multiple exposure units can be responsible for a portion of the printing area and for a different clipping layer. The clipping layer may serve as a filter to inform layout-processing software to keep patterns to be printed by a particular exposure unit on the clipping layer associated with that exposure unit. More specifically, each exposure unit can expose a corresponding scan region of a substrate to an amount of energy, referred herein to as a “dose.” For example, the dose can correspond to some quantity of photons emitted by the exposure unit that are incident on the scan region.

However, exposure units can have unique characteristics that do not match exactly with other exposure units. This mismatch can result in non-uniformity (e.g., unevenness, inconsistency, irregularity) during stitching and visible defects, also referred to as “mura.” Mura is a term of Japanese origin that generally refers to any visible defect, such as visible variation, that is visible across a display device because of the scanning process (e.g., stitching). In some instances, mura can include visible boundaries between regions printed by pairs of adjacent exposure units. The existence of mura can render a display device defective for its intended purpose. For example, humans can visually observe these defects, which can affect display quality. Accordingly, reducing mura can improve display device manufacture throughput as well as display device quality.

Aspects and implementations of the present disclosure address these and other shortcomings of existing technologies by performing exposure unit boundary smoothing to reduce non-uniformity within regions scanned by adjacent exposure units. The blending can create more gradual transitions between boundaries to reduce the appearance of visible irregularities observable to the human eye. Accordingly, embodiments described herein can be used to improve display device quality and throughput.

The exposure unit boundary smoothing can be performed to smooth both EYE-to-EYE (E2E) boundaries and bridge-to-bridge (B2B) boundaries in multiple directions. An E2E boundary refers to a boundary separating adjacent scan regions each defined for a respective exposure unit of a pair of exposure units attached to the same bridge (e.g., a first exposure unit and a second exposure unit each attached to the same bridge). A B2B boundary refers to a boundary separating adjacent scan regions each defined for a respective exposure unit of a pair of exposure units attached to different bridges (e.g., a first exposure unit attached to a first bridge and a second exposure unit attached to a second bridge adjacent to the first bridge).

More specifically, performing the exposure unit boundary smoothing can include performing a combination of dithering and dose mixing to reduce the appearance of mura. For example, reducing the appearance of mura can include reducing the appearance of E2E boundaries and/or B2B boundaries observable to the human eye.

Dithering involves, for each exposure unit of a pair of adjacent exposure units, controlling which portions of a scan region (“sub-regions”) that the exposure unit is responsible for scanning. More specifically, a single exposure unit of the pair of exposure units will provide a target dose for a particular sub-region. A target dose for an exposure unit can be defined as a respective amount of dose (e.g., amount of energy or number of photons) that the exposure unit provides relative to a total possible dose (“total dose”).

Dose mixing involves, for a pair of adjacent exposure units, controlling the target dose that each exposure unit provides within a scan region. A target dose for an exposure unit can be defined as a respective amount of dose (e.g., amount of energy or number of photons) that the exposure unit provides relative to the total dose. For example, a first exposure unit of the pair can be controlled to provide a dose that is X % of the total dose within a scan region, and a second exposure of the pair can be controlled to provide a dose that is Y % of the total dose within the scan region, where the sum of X and Y is 1 (e.g., 100% of the total dose). The percentage of the total dose provided by the first and second exposure units can be selectively controlled depending on where the scan region is located.

More specifically, performing the combination of dithering and dose mixing can include controlling the dithering in a first direction. In some embodiments, the first direction is the scan direction. For example, the scan direction can be a horizontal direction as observed from a top-down view of the digital lithography system (e.g., from left-to-right). Dithering can be controlled for a first pair of adjacent exposure units including a first exposure unit attached to a first bridge and second exposure unit attached to a second bridge adjacent to the first bridge, where a nominal B2B boundary separates a first scan region defined for the first exposure unit and a second scan region defined for the second exposure unit. More specifically, one of the first exposure unit or the second exposure unit can be selected to provide its target dose based on a position of the exposure unit relative to the underlying substrate along the scan direction. For example, the first exposure unit can be assigned to provide its target dose in a first sub-region, the second exposure unit can be assigned to provide its target dose in a second sub-region, and the first exposure unit and the second exposure unit can each be assigned to provide its target dose within a third sub-region having a total area. The third sub-region can be referred to as a B2B blending zone. More specifically, the B2B blending zone can be divided into multiple sub-zones, where each sub-zone of the B2B blending zone is each formed from a respective portion of the total area of the B2B blending zone. Each sub-zone of the B2B blending zone can have an associated area ratio defining an amount of area within the sub-zone that the first exposure unit is assigned to scan and the amount of area that the second exposure unit is assigned to scan.

Performing the combination of dithering and dose mixing can further include controlling the dose mixing in a second direction perpendicular to the first direction (e.g., perpendicular to the scan direction). For example, the second direction can be a vertical direction as observed from a top-down view of the digital lithography system. Dose mixing can be controlled for a second pair of adjacent exposure units including a third exposure unit and a fourth exposure unit attached to the same bridge, where a nominal E2E boundary separates a third scan region defined for the third exposure unit and a fourth scan region defined for the fourth exposure unit. More specifically, the target dose assigned to each of the third exposure unit and the fourth exposure unit is based on a position of the exposure unit relative to the underlying substrate along the direction perpendicular to the scan direction.

The dithering performed between the first pair of adjacent exposure units in the first direction can interact with the dose mixing performed between the second pair of adjacent exposure units in the second direction. For example, the first exposure unit described above can also be the third exposure unit, such that the first pair of adjacent exposure units includes the first exposure unit and the second exposure unit, and the second pair of adjacent exposure units includes the first exposure unit and the fourth exposure unit. Accordingly, a B2B boundary can separate the first and second exposure units, an E2E boundary can separate the first and fourth exposure units, and a target dose determined for the first exposure unit in accordance with the dose ratio for dose mixing with respect to the second exposure unit is the target dose that is applied in accordance with the area ratio for dithering with respect to the fourth exposure unit.

Aspects and implementations of the present disclosure result in technological advantages over other approaches. For example, as mentioned above, embodiments described herein can reduce the appearance of mura, such as visible boundaries caused by non-uniformity of adjacent exposure units. Accordingly, embodiments described herein can achieve improved photolithography for substrate patterning.

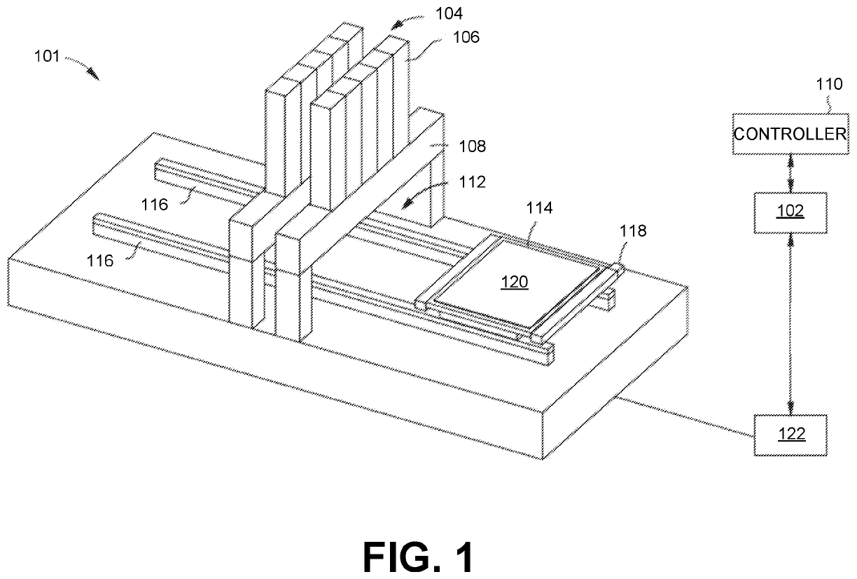

FIG. 1 is a schematic partial perspective view of a digital lithography system (“system”) 100, in accordance with some embodiments. The system 100 can include a digital lithography subsystem (“subsystem”) 101. The subsystem 101 can include a stage 114 and a processing unit 104. The stage 114 is supported by a pair of tracks 116. A substrate 120 is supported by the stage 114. The stage 114 is operable to move along the pair of tracks 116. The stage 114 can move on the tracks 116 in the x-direction and the y-direction as defined in FIG. 1. The processing unit 104 is configured to expose the photoresist in the digital lithography process using one or more image projection systems (IPSs) 106. The IPSs 106 are supported by supports 108 that are adjacent to (e.g., straddle) the pair of tracks 116. The supports 108 provide an opening 112 for the pair of tracks 116 and the stage 114 to pass under the processing unit 104. The subsystem 101 can further include an encoder coupled to a stage.

The substrate 120 can be formed from any suitable material or combinations of materials, for example, glass, which is used as part of a flat panel display. In other embodiments, which can be combined with other embodiments described herein, the substrate 120 is made of other materials capable of being used as a part of the flat panel display. The substrate 120 has a film layer to be patterned formed thereon, such as by pattern etching thereof, and a photoresist layer formed on the film layer to be patterned, which is sensitive to electromagnetic radiation (e.g., UV). A positive photoresist includes portions of the photoresist, when exposed to radiation, are respectively soluble to a photoresist developer applied to the photoresist after the pattern is written into the photoresist using the electromagnetic radiation. A negative photoresist includes portions of the photoresist, when exposed to radiation, will be respectively insoluble to photoresist developer applied to the photoresist after the pattern is written into the photoresist using the electromagnetic radiation. The chemical composition of the photoresist determines whether the photoresist is a positive photoresist or negative photoresist. Examples of photoresists include, but are not limited to, at least one of diazonaphthoquinone, a phenol formaldehyde resin, poly(methyl methacrylate), poly(methyl glutarimide), and SU-8. After exposure of the photoresist to the electromagnetic radiation, the resist is developed to leave an exposure underlying film layer. Then, using the patterned photoresist, the underlying thin film is pattern etched through the openings in the photoresist to form a portion of the electronic circuitry of the display panel.

The system 100 can further include a lithography controller 122 and a controller 110 communicably coupled to the subsystem 101. For example, the encoder 118 can provide information regarding the location of the stage 114 to the lithography controller 122. The lithography controller 122 is generally designed to facilitate the control and automation of the processing techniques described herein. The lithography controller 122 may be coupled to or in communication with the processing unit 104, the stage 114, and the encoder 118. The processing unit 104 and the encoder 118 may provide information to the lithography controller 122 regarding the substrate processing and the substrate aligning. For example, the processing unit 104 may provide information to the lithography controller 122 to alert the lithography controller 122 that substrate processing has been completed. The controller 110 is operable to deliver one or more virtual mask files corresponding to exposure patterns or the controller 110 is otherwise configured to perform processes described herein. The lithography controller 122 can facilitate the control and automation of a digital lithography process based on a virtual mask file provided by a virtual mask software application 102. The virtual mask file, readable by the lithography controller 122, determines which tasks are to be performed on a substrate. The virtual mask file corresponds to an exposure pattern to be written into the photoresist using the electromagnetic radiation.

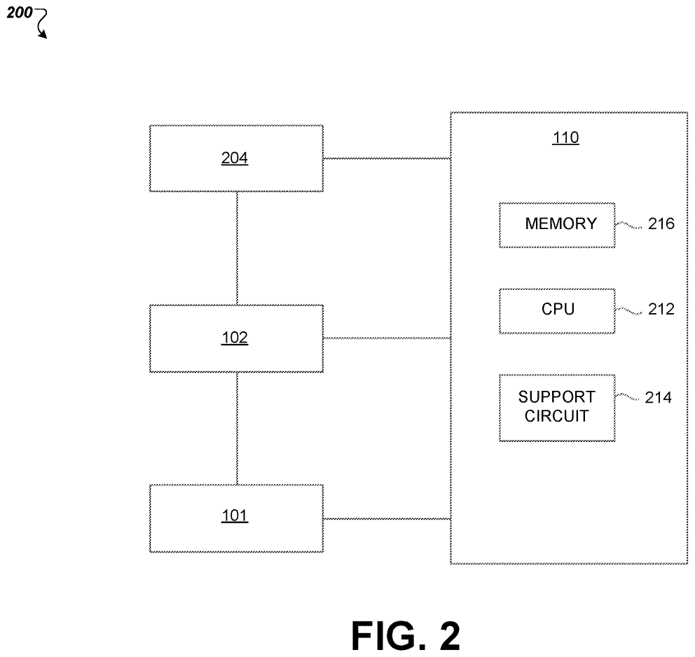

The processing unit 104 can include a pattern generator configured to receive a virtual mask file from the virtual mask software application 102. The virtual mask file can be provided to the processing unit 104 via the lithography controller 122. The processing unit 104 is configured to expose the photoresist in the digital lithography process using the one or IPSs 106. The one or more IPSs 106 are operable to project write beams of electromagnetic radiation to the substrate 120. The exposure pattern generated by the processing unit 104 is projected by the IPSs 106 to expose the photoresist of the substrate 120 to the exposure pattern. The exposure of the photoresist forms one or more different features in the photoresist. In one embodiment, which can be combined with other embodiments described herein, each IPS 106 includes a spatial light modulator to modulate the incoming light to create the desired image. Each spatial light modulator includes a plurality of electrically addressable elements that may be controlled individually. Each electrically addressable element may be in an “ON” position or an “OFF” position based on the digital pattern file 204 (shown in FIG. 2). When the light reaches the spatial light modulator, the electrically addressable elements that are in the “ON” position project a plurality of write beams to a projection lens (not shown). The projection lens then projects the write beams to the substrate 120. The electrically addressable elements include, but are not limited to, digital micromirrors, liquid crystal displays (LCDs), liquid crystal over silicon (LCoS) devices, ferroelectric liquid crystal on silicon (FLCoS) devices, microshutters, microLEDs, VCSELs, liquid crystal displays (LCDs), or any solid state emitter of electromagnetic radiation.

FIG. 2 is a block diagram of a digital lithography system (“system”) 200, in accordance with some embodiments. As shown, the system 200 can include the subsystem 101, the virtual mask software application 102 and the controller 110 described above with reference to FIG. 1. The controller 110 is operable to facilitate the transfer of a digital pattern file 204 (e.g., data) provided to the controller 110. The controller 110 is operable to execute a virtual mask software application 102 to convert the digital pattern file 204 into a virtual mask file (not shown) having an exposure pattern readable by the processing unit 104. Each of the lithography environment devices is operable to be connected to each other via the communication links 101. Each of the lithography environment devices is operable to be connected to the controller 110 by the communication links 101. The lithography environment 200 can be located in the same area or production facility, or the each of the lithography environment devices can be located in different areas.

The controller 110 includes a central processing unit (CPU) 212, support circuits 214 and a memory 216. The CPU 212 can be one of any form of computer processor that can be used in an industrial setting for controlling the lithography environment devices. The memory 216 is coupled to the CPU 212. The memory 216 can be one or more of readily available memory, such as random access memory (RAM), read only memory (ROM), floppy disk, hard disk, or any other form of digital storage, local or remote. The support circuits 214 are coupled to the CPU 212 for supporting the processor. For example, the support circuits 214 can include cache, power supplies, clock circuits, input/output circuitry, subsystems, and the like. The CPU 212 can be coupled to input/output (I/O) devices found in the support circuits 214 and the memory 216. The controller 110 is operable to facilitate and transfer the digital pattern file 204 to the digital lithography system 100 via the communication links 101. The digital pattern file 204 is operable to be provided to the virtual mask software application 102 or the digital lithography system 100 via the controller 110.

The memory 216 can include one or more software applications, such as the virtual mask software application 102. The CPU 212 can be a hardware unit or combination of hardware units capable of executing software applications and processing data. In some configurations, the CPU 212 includes a digital signal processor (DSP), an application-specific integrated circuit (ASIC), and/or a combination of such units. The CPU 212 is configured to execute the one or more software applications, such as the virtual mask software application 102 and process the stored media data, which can be each included within the memory 216. The controller 110 controls the transfer of data and files to and from the various lithography environment devices.

The controller 110 is operable to receive exposure patterns of the virtual mask file and transfer the exposure patterns to the digital lithography system 100 via the communication links 101. The virtual mask file (or computer instructions), which may be referred to as an imaging design file, readable by the controller 110, determines which tasks are performable on a substrate. While the virtual mask software application 102 is illustrated as separate from the controller 110 (e.g., in the cloud), it is contemplated that the virtual mask software application 102 may be stored locally (e.g., in memory 216).

The virtual mask file corresponds to a pattern to be written into the photoresist using electromagnetic radiation output by the digital lithography system 100. In one embodiment, which can be combined with other embodiments described herein, the pattern may be formed with one or more patterning devices. For example, the one or more patterning devices are configured to perform ion-beam etching, reactive ion etching, electron-beam (e-beam) etching, wet etching, nanoimprint lithography (NIL), and combinations thereof. The virtual mask file may be provided in different formats. For example, the format of the virtual mask file may be one of a GDS format, and an OASIS format, among others. The virtual mask file includes information corresponding to features of exposure patterns to be generated on a substrate (e.g., the substrate 120). The virtual mask file may include areas of interest which correspond to one or more structural elements. The structural elements may be constructed as geometrical shapes (e.g., polygons).

The lithography model can be a physics based model. For example, the lithography model can use either a scalar or vector imaging model. In some embodiments, the lithography model utilizes a matrix defined by optical properties and/or photoresist properties. For example, the matrix can include Transmission Cross Coefficients (TCC). In some embodiments, other numerical simulation techniques such as Resolution Enhancement Technology (RET), Optical Proximity Correction (OPC), and Source Mask Optimization (SMO) may be utilized. However, all such models and modeling techniques, whether now known or later developed, are intended to be within the scope of the present disclosure. The lithography model can be constructed to be defined based on optical properties (e.g., optical properties relating to the digital lithography system 100) and the photoresist properties (e.g., properties of the photoresist of which the pattern will be printed on such as materials and processing characteristics of the photoresist). The photoresist properties include numerical aperture, exposure, illumination type, size of illumination, and wavelength, and may include other values.

Once the lithography model is constructed, the virtual mask file can be provided as input to the lithography model. The lithography model can then outputs a prediction of the aerial image and resist profile of the virtual mask file. Through post-processing operations, the ILS and depth of focus of features formed in a photoresist of a substrate based on the virtual mask file may be determined. The lithography model will utilize numerical calculations to predict variables to achieve the maximum ILS and depth of focus (or a maximum ILS and depth of focus within other predefined constraints). The variables include a width and position and a pattern bias value of the exposure patterns. The numerical calculations may be iterative methods, level-set methods, or any other numerical methods operable to solve the lithography model.

The controller 110 provides the digital pattern file 204 to the virtual mask software application 102. The virtual mask software application 102 is operable to receive the digital pattern file 204 via the communication links 101. The virtual mask software application 102 can be a vMASC software. In one embodiment, which can be combined with other embodiments described herein, the virtual mask software application 102 is a software program stored in the memory 216 of the controller 110. The CPU 212 is configured to execute the software program. In another embodiment, which can be combined with other embodiments described herein, the virtual mask software application 102 may be a remote computer server which includes a controller and a memory (e.g., data store).

The digital pattern file 204 can be converted into one or more virtual mask files by the virtual mask software application 102. For example, a first virtual mask file may correspond to an exposure pattern and a second virtual mask file may correspond to another exposure pattern. The virtual mask file is a digital representation of the design to be printed by the digital lithography system 100. The virtual mask file is provided to the digital lithography system 100 via the communication links 101. The virtual mask file is stored in the digital lithography system 100.

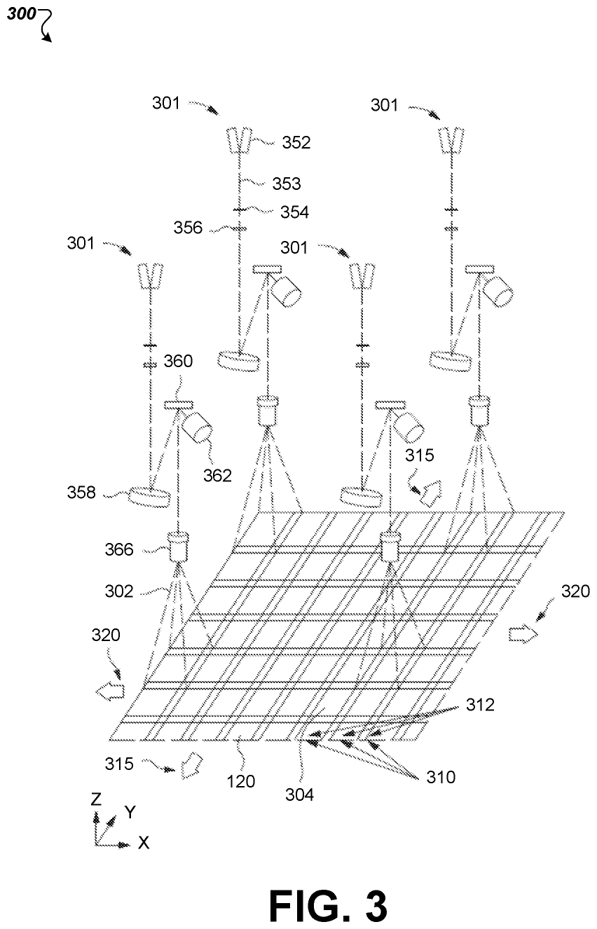

FIG. 3 is a diagram of a system 300 including multiple IPSs 301, in accordance with some embodiments. As shown in FIG. 3, each of the IPSs 301 can generate write beams 302 onto a surface 304 of the substrate 120, corresponding to a plurality of processing positions 312, along a plurality of tracks 116, each of the tracks 116 to be scanned by one or more of the write beams 302. The movement of the substrate 120 is in an in-scan direction indicated by arrow 315, while the cross-scan direction is indicated by arrow 320. As the substrate 120 moves in the in-scan direction and cross-scan direction, the entire surface 304 may be patterned by the write beams 302. The number of the IPSs 301 may vary based on the size of the substrate 120 and/or the speed of stage 114. In one embodiment, there are 10 IPSs 301 in the processing unit 104.

Each of the IPSs 301 can include a light source 352, an aperture 354, a lens 356, a frustrated prism assembly 358, a spatial light modulator (SLM) 360 and a projection optical device 366. The components of each of the plurality of IPSs 301 vary depending on the SLM 360 being used. Each SLM 360 includes, but is not limited to, an array of microLED's, VCSEL's, liquid crystal displays (LCDs), or any solid-state emitter of electromagnetic radiation, and a digital mirror device (DMD). Each SLM 360 can include a plurality of SLM pixels. Each SLM pixel can be individually controllable to project a write beam. The compilation of plurality of SLM pixels forms the pattern written into the photoresist, referred to herein as the mask pattern. Each projection optics 366 includes projection lenses, for example, 10× objective lenses, used to project light onto the substrate 120. In operation, based on the mask pattern data provided to the SLM 360 by the controller 110, each SLM pixel is at an “on” position or “off” position. Each SLM pixel at an “on” position forms a write beam that the corresponding projection optical device 366 then projects the write beam to the photoresist layer surface of the substrate 120 to form a pixel of the mask pattern. In some embodiments, each SLM 360 includes a plurality of mirrors, e.g., the plurality of SLM pixels. Each mirror of the plurality of mirrors corresponds to an SLM pixel that may correspond to a pixel of the mask pattern. In some embodiments, an SLM 360 is a DMD. In some embodiments, the DMD includes more than about 4,000,000 mirrors, while in other embodiments may include 1920×1080 mirrors, which represent the number of pixels of a high definition television.

The light source 352 is any suitable light source, such as a light emitting diode (LED) or a laser, capable of producing a light having a predetermined wavelength. In one embodiment, the predetermined wavelength is in the blue or near UV range, such as less than about 450 nm. The frustrated prism assembly 358 includes a plurality of reflective surfaces. In operation, a light beam 453 having is produced by the light source 352. The light beam 353 is reflected SLM 360 by the frustrated prism assembly 358. When the light beam 353 reaches the mirrors of the SLM 360, each mirror at the “on” position reflects the light beam 353 to the projection optical system 366. The projection optical system 366 then projects a plurality of write beams (e.g., “shots”) 302 onto the photoresist layer surface of the substrate 120. The plurality of write beams 302 forms a plurality of pixels of the mask pattern.

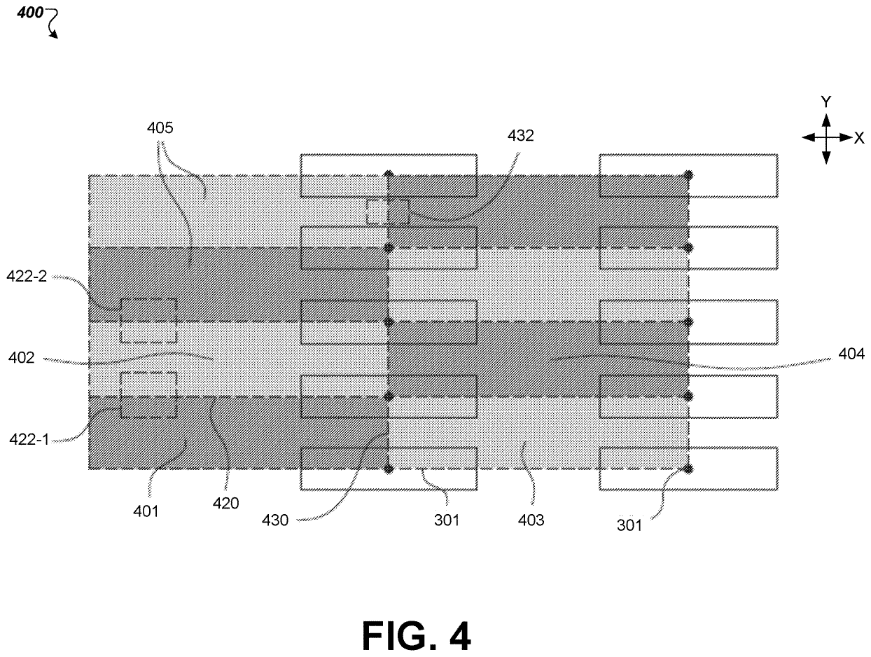

FIG. 4 is a top-down view of a digital lithography system 400, in accordance with some embodiments. For example, system 400 shows a portion of the substrate 120 underneath the processing unit 104. The substrate 120 can be divided into sections 405 defining E2E boundaries 420 having associated E2E boundary regions including E2E boundary regions 422-1 and 422-2, and B2B boundaries 430 having associated B2B boundary regions including B2B boundary region 432. In this illustrative example, there are 10 IPSs 301 and the substrate 120 is divided into eight sections (e.g., scan regions) 405 including at least one first section 401, one second section 402, one third section 403, and one fourth section 404. Each section 405 corresponds to a respective exposure unit of an IPS. However, the number of sections should not be considered limiting.

Each of the sections 405 have a section pattern. Boundaries between first section 401 and a second section 402 which are along a column of IPSs 301 are E2E boundaries 420. The boundary between the third section 403 and the fourth section 404 are also E2E boundaries. Boundaries between first section 401 and a third section 403 which are along a row of IPSs 301 are B2B boundaries 430. The boundary between the second section 402 and the fourth section 404 are also B2B boundaries 430. Each IPS is operable to expose a respective section (e.g., one of a first section 401, a second section 402, and a third section 403, and a fourth section 404) pattern the sections 405 to a section pattern and a portion of a section on the E2E boundary 420, and another portion of a section of the B2B boundary 430. For example, for an IPS 301 the exposure area corresponds to the first section 401, a portion of the second section 402 on the E2E boundary 420, a portion of the third section 403 on the B2B boundary 430, and another portion of a fourth section 404 where the E2E boundary 420 meets the B2B boundary 430. For an IPS 301 the exposure area corresponds to the second section 402, a portion of the first section 401 on the E2E boundary 420, a portion of the fourth section 404 on the B2B boundary 430, and another portion of a third section 403 where the E2E boundary 420 meets the B2B boundary 430.

The substrate 120 can include a photoresist material disposed on a material to be etched. The photoresist material can be a positive photoresist material (e.g., where a portion of the photoresist material that is exposed to radiation (e.g., light) becomes soluble to a photoresist developer) or a negative photoresist material (e.g., where a portion of the photoresist material that is exposed to radiation (e.g., light) becomes insoluble to a photoresist developer). Thus, by removing designated portions of the photoresist material, a photoresist pattern can be formed. In some embodiments, the material to be etched is a conductive material (e.g., metal). For example, the conductive material can be molybdenum. After the designated regions of the photoresist material are removed, the now-exposed material can be etched in accordance with the photoresist pattern. For example, wiring can be formed during the etch process. Alternatively, the patterned material can itself be photosensitive, eliminating the need to add a photoresist layer and performing the following etch process.

During a digital lithography process, each exposure unit is moved relative to the substrate to expose a region (e.g., a rectangular region) of the substrate to radiation (e.g., light). During scanning, the exposure units expose respective scan regions, in accordance with a programmed scan path. Instead of having the exposure units move above the stage assembly, the stage assembly can move in the X-Y direction underneath the exposure units in accordance with the programmed scan path. Since the field-of-view of a lens assembly (e.g., lens assembly) can be smaller than its associated scan region, the stage assembly may have to move back and forth repeatedly until the entire scan region is printed. The lens assembly is projected to scan the scan region, except for the first and last scans where trimming may occur based on the definition of the scan region. The greater the number of exposure units, the fewer scans that may be performed, which can correspond to higher throughput.

Each exposure unit can be responsible for a different scan region, which may or may not overlap with the adjacent scan regions of other exposure units. To avoid abrupt transitions from a first scan region to a second scan region adjacent to the first scan region (either attached to the same bridge or to a different bridge), the exposure unit corresponding to the first scan region can encroach into the second scan region. Similarly, the exposure unit corresponding to the second scan region can encroach into the first scan region. Accordingly, shared exposures can be observed at boundaries or “stitching lines” between adjacent exposure units of the same bridge and/or exposure units on different bridges.

A stitching line can be defined by a clipping layer, which can be a software-defined layer that sets the scan path boundary for each exposure unit during movement of the stage assembly. A stitching line may be visible on the substrate after printing due to non-ideal printing conditions. For example, if the actual location of an exposure unit is shifted by about 1 micron, there may be a 1 micron-wide gap or double exposed band near the stitching line. Although the stitching lines in this illustrative example are shown as straight lines (such that the scan regions are rectangular shaped), the stitching lines can be curvy (e.g., wavy).

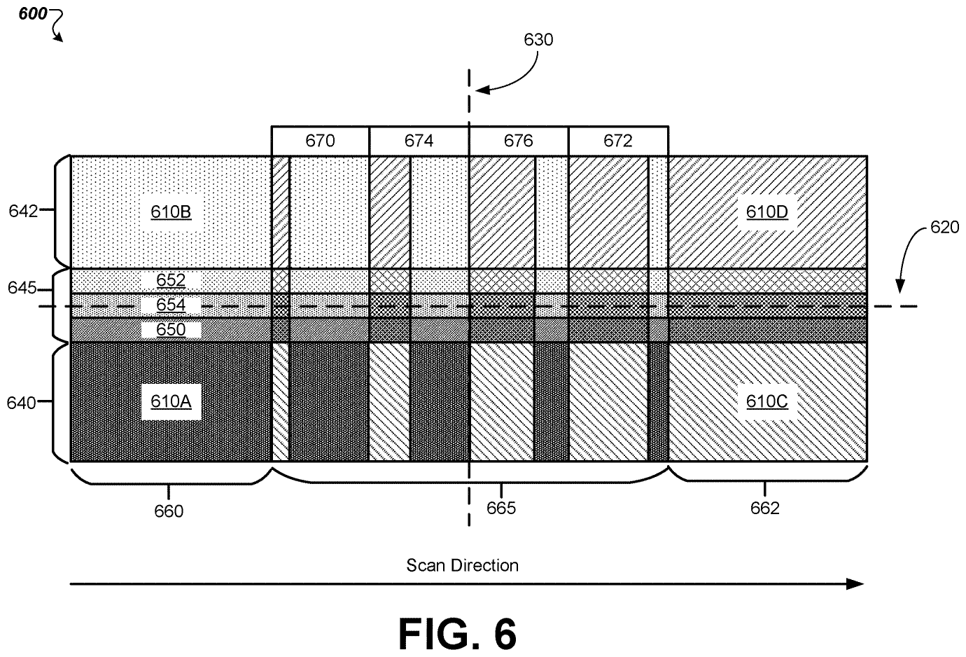

As will be described in further detail below with reference to FIGS. 6A-D, an exposure unit can proceed in in a path during scanning. More specifically, during scanning, the stage assembly moves in the X direction (e.g., from right to left) across the scan region, during which time the exposure unit patterns a line across the scan region. The stage assembly, upon reaching the left edge of the scan region, moves in the Y-direction (e.g., up), and then moves in the X-direction (e.g., from left to right) to pattern another line across the scan region. The path proceeds in this snake-like fashion until reaching the opposite end of the scan region, at which point a full image has been patterned on the substrate. The image can then be developed for substrate etching. The distance of stage travel in the Y-direction during scanning, “Y₁”, can be any suitable distance in accordance with the embodiments described herein. In some embodiments, Y₁ can range between about 150 mm and about 180 mm. For example, Y₁ can be about 164 mm. The scan distance in the X direction for each exposure unit corresponds to the length of the bridges and in some embodiments. The total width of the scan regions, “Y₂”, can be any suitable width in accordance with the embodiments described herein. In some embodiments, “Y₂” can range between about 1600 mm and about 2000 mm. For example, Y₂ can be about 1800 mm. The travel distance for each scan (e.g., in the X-direction) can be different due to differences in substrate size. For example, in some embodiments, the substrate includes an 8-inch round wafer. As another example, in some embodiments, the substrate includes a 12-inch round wafer.

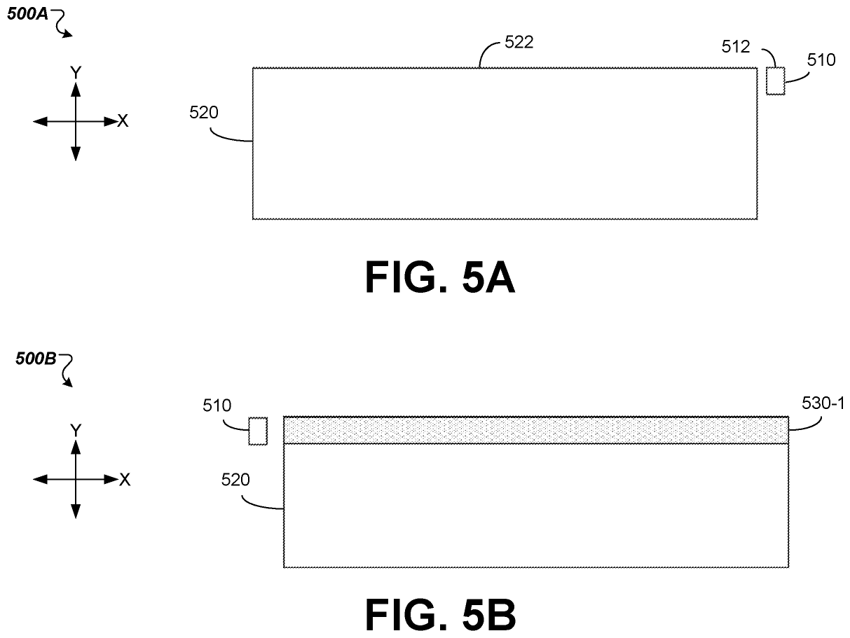

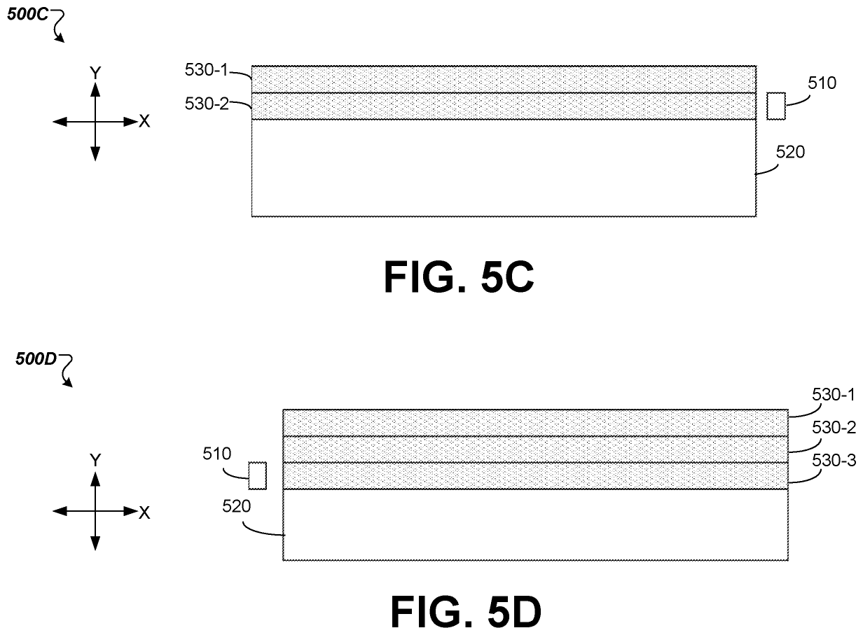

FIGS. 5A-5D are top-down views 500A-500D of a scan path of a substrate 520 through a single digital lithography exposure unit (“exposure unit”) 510 of a digital lithography system, in accordance with some embodiments.

FIG. 5A shows the exposure unit 510 and a scan region 520 of a substrate prior to a first scan being performed using the exposure unit 610. An edge 522 of the scan region 520 can be aligned with an edge 512 of the exposure unit 510 prior to a first scan performed. The stage moves the substrate in the X-Y direction(s) in accordance with a digital lithography scanning procedure performing a number of scans across the scan region 520.

FIG. 5B shows the formation of a scanned area 530-1 within the scan region 520 after the first scan is performed using the exposure unit 510. More specifically, the stage moves the substrate in the positive X direction underneath the exposure unit 510 to form the scanned area 530-1.

FIG. 5C shows the formation of a scanned area 530-2 after a second scan is performed using the exposure unit 510. More specifically, after the first scan is performed using the exposure unit 510, the stage moves the substrate in the positive Y direction to align the exposure unit 510 with the next designated region, and then the stage moves the substrate in the negative X direction underneath the exposure unit 510 to form the scanned area 530-2.

FIG. 5D shows the formation of a scanned area 530-2 after a second scan is performed using the exposure unit 510. More specifically, after the second scan is performed using the exposure unit 510, the stage moves the substrate in the positive Y direction to align the exposure unit 510 with the next designated region, and then the stage moves the substrate 520 in the positive X direction underneath the exposure unit 610 to form the scanned area 530-3. Additional scans can be performed to finish the scanning.

During the scanning process described above, one or more “mura” problems can be observed. One example of mura is “scan mura” that occurs after every scan. For example, one type of scan mura is illumination non-uniformity, in which the exposure field of an exposure unit is inconsistent (e.g., a top edge of the exposure field has a different illumination field than a bottom edge). More specifically, every time a scan is performed to scan a line or “paint a stripe,” the top edge of the scan will be brighter or dimmer than the bottom edge. This can adversely affect the patterning dimensions. Another example of mura is “vibrational mura,” where vibrations resulting from operation of the digital lithography system can cause exposure units to vibrate, resulting in scan choppiness. Since the exposure unit vibrations may not be spatially synchronized, this can result in visible variations across the display.

Another example of mura is “boundary mura,” in which an abrupt change in appearance can be observed at the boundary or edge of a region scanned by one exposure unit and an adjacent region scanned by another exposure unit. For example, boundary mura can occur at the boundary between regions scanned by a pair of adjacent exposure units of a given bridge (e.g., the boundary between scan regions). As another example, boundary mura can occur at the boundary between regions scanned by a pair of adjacent exposure units corresponding to different bridges (e.g., the boundary between scan regions).

There can be a variety of different microscopic and/or macroscopic causes of boundary mura. For example, if one exposure unit is outputting more radiation (e.g., light) than an adjacent exposure unit during scanning, then a sudden change in the line widths of the printed lines can be observed across the boundary between the exposure units. As another example, if one exposure unit is out of focus compared to the other exposure unit, then a photoresist sidewall profile corresponding to each exposure unit can be different. For example, the exposure unit with better focus can have a more vertical sidewall, as compared to a more sloped sidewall of the exposure unit with poorer focus. Accordingly, problems can exist at the boundaries of adjacent scan regions.

As will be described in further detail herein, mura (e.g., boundary mura) can be addressed by performing exposure unit boundary smoothing to smooth the boundaries (e.g., stitching lines) between scan regions scanned by adjacent exposure units. An exposure unit boundary may correspond to an edge of a region scanned by an exposure unit. For example, exposure unit boundary smoothing can be performed to create a gradual transition between regions scanned by different exposure units (e.g., blend the boundary).

FIG. 6 is a diagram 600 illustrating exposure unit boundary smoothing performed by a digital lithography system from a top-down view, in accordance with some embodiments. For example, the digital lithography system can include one or more of systems 100-400 of FIGS. 1-4. For example, diagram 600 shows a plurality of scan regions. The plurality of scan regions include exposure unit (EYE) A scan region 610A corresponding to EYE A, EYE B scan region 610B corresponding to EYE B, EYE C scan region 610C corresponding to EYE C, and EYE D scan region 610D corresponding to EYE D. EYE A and EYE B are attached to a first bridge and EYE C and EYE D are attached to a second bridge different from and adjacent to the first bridge. EYE A and EYE B define a first pair of adjacent EYEs (e.g., a pair of adjacent EYEs attached to the same bridge). EYE C and EYE D define a second pair of adjacent EYEs (e.g., a pair of adjacent EYEs attached to the same bridge). EYE A and EYE C define a third pair of adjacent EYEs (e.g., a pair of adjacent EYEs attached to different bridges). EYE B and EYE D define a fourth pair of adjacent EYEs (e.g., a pair of adjacent EYEs attached to different bridges).

The first and second pairs of adjacent EYEs are separated by nominal E2E boundary 620 and the third and fourth pairs of adjacent EYEs are separated by nominal B2B boundary 630. Accordingly, EYE A scan region 610A corresponds to a bottom-left quadrant defined by nominal E2E boundary 620 and nominal B2B boundary 630, EYE B scan region 610B corresponds to a top-left quadrant defined by nominal E2E boundary 620 and nominal B2B boundary 630, EYE C scan region 610C corresponds to a bottom-right quadrant defined by nominal E2E boundary 620 and nominal B2B boundary 630, and EYE D scan region 610D corresponds to a top-right quadrant defined by nominal E2E boundary 620 and nominal B2B boundary 630. In this example, a scan direction of the scan paths taken by EYEs A-D is shown as a horizontal direction proceeding from left to right. Further details regarding the scan path are described above with reference to FIGS. 4-5D.

In this example, dose mixing can be controlled for the first and second pairs of adjacent EYEs in the direction perpendicular to the scan direction. More specifically, the target doses assigned to EYE A and EYE B of the first pair of adjacent EYEs, and the target doses assigned to EYE C and EYE D of the second pair of adjacent EYEs, are based on positions relative to the underlying substrate along the direction perpendicular to the scan direction.

For example, EYEs A and C can each be assigned to provide the total dose in a zone 640, EYEs B and D can each be assigned to provide the total dose in a zone 642, EYEs A-D can each be assigned to provide a respective target dose, each less than the total dose, within an E2E blending zone 645 having a total area. More specifically, the E2E blending zone 645 can be divided into multiple sub-zones, where each sub-zone of the E2E blending zone 645 is formed from a respective portion of the total area of the E2E blending zone 645. Each sub-zone of the E2E blending zone 645 can have an associated dose ratio defining the target dose of the third exposure unit and the target dose of the fourth exposure unit within the sub-zone.

Generally, a dose ratio can range from 1: N to N:1, where Nis the number of sub-zones of the E2E blending zone 645. In some embodiments, N can range from 3 to 6. E2E blending zone 645 can have an associated height (H). In some embodiments, H ranges from about 5 mm to about 20 mm. Thus, each sub-zone of the E2E blending zone 645 can have a width of HIN. In this illustrative example, the number of sub-zones of the E2E blending zone 645 is three (e.g., N=3), and each sub-zone of the E2E blending zone 645 can have a width of H/3.

For example, sub-zone 650 of the E2E blending zone 645 can define a dose ratio in which EYEs A and C each provide a target dose equal to about 75% of the total dose and EYEs B and D each provide a target dose equal to about 25% of the total dose. As another example, a sub-zone 652 of the E2E blending zone 645 can be located adjacent to zone 642 and can define a dose ratio in which the EYEs A and C each provide a target dose equal to about 25% of the total dose and EYEs B and D each provide a target dose equal to about 75% of the total dose. As yet another example, sub-zone 654 of the E2E blending zone 645 can be located between sub-zone 650 and sub-zone 625 and can define a dose ratio in which EYEs A, B, C and D each provide a target dose equal to about 50% of the total dose. Accordingly, dose mixing as described herein can be used to perform E2E boundary smoothing between adjacent EYEs attached to the same bridge.

Dithering can be controlled for the third and fourth pairs of adjacent EYEs. More specifically, for the third pair of adjacent EYEs, one of EYE A or EYE C can be selected to provide its target dose (e.g., determined from the dose mixing) based on a position relative to the underlying substrate along the scan direction. For the fourth pair of adjacent EYEs, one of EYE B or EYE D can be selected to provide its target dose (e.g., determined from the dose mixing) based on a position relative to the underlying substrate along the scan direction. For example, EYEs A and B can be assigned to provide its target dose in sub-region 660, EYEs C and D can be assigned to provide its target dose in sub-region 662, and EYEs A-D can each be assigned to provide its target dose within a B2B blending sub-region 650, or B2B blending zone 665, having a total area.

More specifically, B2B blending zone 665 can be divided into multiple sub-zones, where each subzone of the B2B blending zone 665 is formed from a respective portion of the total area of the B2B blending zone 665. Each sub-zone of the B2B blending zone 665 can have an associated area ratio defining an amount of area within the sub-zone that each of EYEs A-D is assigned to scan. Generally, area ratio can range from 1: M to M:1, where M is the number of sub-zones of the B2B blending zone 665. In some embodiments, M can range from 3 to 6. B2B blending zone 665 can have an associated width (W). In some embodiments, W ranges from about 5 mm to about 20 mm. Thus, each sub-zone of the B2B blending zone can have a width of W/M. In this illustrative example, the number of sub-zones of the B2B blending zone is four (e.g., M=4), and each sub-zone of the B2B blending zone can have a width of W/4.

For example, sub-zone 670 of the B2B blending zone 665 can be located adjacent to sub-region 660. The sub-zone 670 can define a first area ratio in which EYEs A and B each scan a portion of the area of the sub-zone 670 and EYEs C and D each scan the remaining portion of the area of the sub-zone 670. In some embodiments, the first area ratio is about 1:4, EYEs A and B each scan about 80% of the area of the sub-zone 670 and EYEs C and D each scan about 20% of the remaining area of the sub-zone 670.

As another example, sub-zone 672 of the B2B blending zone 665 can be located adjacent to the sub-region 662. The sub-zone 672 can define a second area ratio in which EYEs C and D each scan a portion of the area of sub-zone 654 and EYEs A and B each scan the remaining portion of the area of the sub-zone 672. In some embodiments, the second area ratio is about 4:1, EYEs C and D each scan about 80% of the area of the sub-zone 672 and EYEs A and B each scan about 20% of the remaining area of the sub-zone 672.

As another example, sub-zone 674 of the B2B blending zone 665 can be located adjacent to the sub-zone 670. The sub-zone 674 can define a third area ratio in which EYEs A and B each scan a portion of an area of the sub-zone 674 and EYEs C and D each scan the remaining portion of the area of the sub-zone 674. In some embodiments, the third area ratio is about 2:3, EYEs A and B each scan about 60% of the area of the sub-zone 674 and EYEs C and D each scan about 40% of the remaining portion of the area of the sub-zone 674.

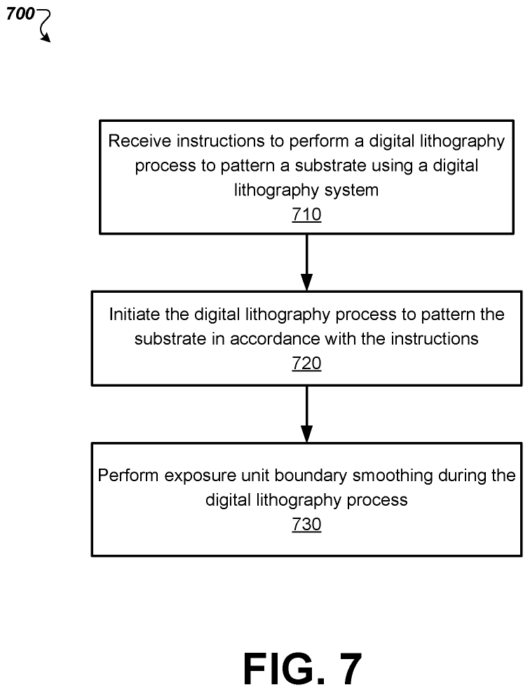

As another example, sub-zone 676 of the B2B blending zone 665 can be located between the sub-zone 672 and the sub-zone 674. The sub-zone 676 can define a fourth area ratio in which EYEs C and D each scan a portion of the area of the sub-zone 676 and EYEs A and B each scan the remaining portion of the area of the sub-zone 676. In some embodiments, the fourth area ratio is about 3:2, EYEs C and D each scan about 60% of the area sub-zone 676 and EYEs A and B each scan about 40% of the remaining area of sub-zone 676. Accordingly, dithering as described herein can be used to perform B2B boundary smoothing between adjacent EYEs attached to different bridges. Further details regarding FIG. 6 are described above with reference to FIGS. 1-5 and will now be described below with reference to FIG. 7.

FIG. 7 depicts a flow diagram of a method 700 for implementing digital lithography exposure unit boundary smoothing, in accordance with some embodiments. The method may be performed by processing logic that may comprise hardware (circuitry, dedicated logic, etc.), computer readable instructions (run on a general purpose computer system or a dedicated machine), or a combination of both. In an illustrative example, method 700 may be performed by a processing device of a digital lithography system. It should be noted that blocks depicted in FIG. 7 could be performed simultaneously or in a different order than that depicted.

At block 710, the processing logic receives instructions to perform a digital lithography process to pattern a substrate using a digital lithography system, and at block 720, the processing logic initiates the digital lithography process to pattern the substrate in accordance with instructions. The substrate can be disposed on the stage, and the stage can move in X-Y directions underneath exposure units in accordance with the instructions. For example, the instructions can be executed to implement exposure unit boundary smoothing (e.g., exposure unit boundary shifting and/or dose mixing).

At block 730, the processing logic performs exposure unit boundary smoothing during the digital lithography process. The exposure unit boundary smoothing can be performed to reduce non-uniformity within scan regions scanned by adjacent exposure units (EYEs). EYE boundary smoothing can blend boundaries, such as B2B boundaries and/or E2E boundaries, to create more gradual transitions between the boundaries to reduce the appearance of visible irregularities observable to the human eye. In some embodiments, the EYE boundary smoothing is performed to smooth both E2E boundaries and B2B boundaries in multiple directions.

In some embodiments, performing EYE boundary smoothing during the digital lithography process includes controlling an area ratio in a first direction with respect to a first pair of adjacent EYEs (e.g., controlling dithering in the first direction) and controlling a dose ratio in a second direction perpendicular to the first direction with respect to a second pair of adjacent EYEs (e.g., controlling dose mixing in the second direction). In some embodiments, the first direction is the scan direction, and the second direction is a direction perpendicular to the scan direction. For example, the scan direction can be a horizontal direction as observed from a top-down view of the digital lithography system (e.g., from left-to-right).

The first pair of adjacent EYEs can include a first EYE attached to a first bridge and second EYE attached to a second bridge adjacent to the first bridge, where a nominal B2B boundary separates a first scan region defined for the first EYE and a second scan region defined for the second EYE. More specifically, one of the first EYE or the second EYE can be selected to provide its target dose based on a position of the EYE relative to the substrate along the first direction. For example, the first EYE can be assigned to provide its target dose in a first sub-region, the second EYE can be assigned to provide its target dose in a second sub-region, and the first EYE and the second EYE can each be assigned to provide its target dose within a third sub-region having a total area. The third sub-region can be referred to as a B2B blending zone. More specifically, the B2B blending zone can be divided into multiple sub-zones, where each sub-zone of the B2B blending zone is each formed from a respective portion of the total area of the B2B blending zone. Each sub-zone of the B2B blending zone can have an associated area ratio defining an amount of area within the sub-zone that the first EYE is assigned to scan and the amount of area that the second EYE is assigned to scan.

The second pair of adjacent EYEs can include a third EYE and a fourth EYE attached to the same bridge, where a nominal E2E boundary separates a third scan region defined for the third EYE and a fourth scan region defined for the fourth EYE. The dose ratio can define the target dose of the third EYE and the target dose of the fourth EYE based on a position relative to the substrate along the second direction.

The control of the area ratio with respect to the first pair of adjacent EYEs in the first direction can interact with the control of the dose ratio with respect to the second pair of adjacent EYEs in the second direction. For example, the first EYE can also be the third EYE, such that the first pair of adjacent EYEs includes the first EYE and the second EYE, and the second pair of adjacent EYEs includes the first EYE and the fourth EYE. Accordingly, a B2B boundary can separate the first and second EYEs, an E2E boundary can separate the first and fourth EYEs, and a target dose determined for the first EYE in accordance with the dose ratio for dose mixing with respect to the second EYE is the target dose that is applied in accordance with the area ratio for dithering with respect to the fourth EYE. Further details regarding blocks 710-730 are described above with reference to FIGS. 1-6.

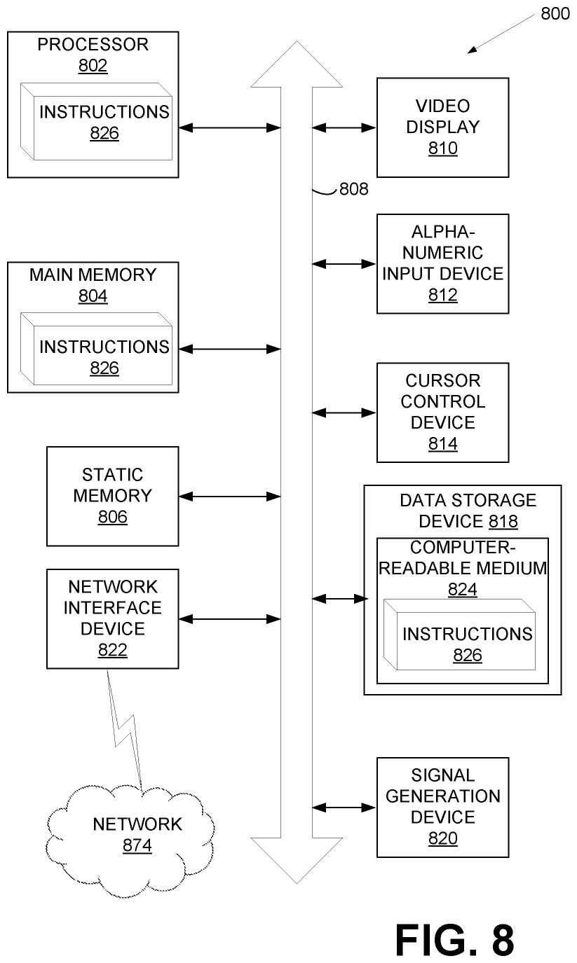

FIG. 8 is a block diagram illustrating a computer system 800, according to certain embodiments. In some embodiments, computer system 800 is connected (e.g., via a network 874, such as a Local Area Network (LAN), an intranet, an extranet, or the Internet) to other computer systems. In some embodiments, computer system 800 operates in the capacity of a server or a client computer in a client-server environment, or as a peer computer in a peer-to-peer or distributed network environment. In some embodiments, computer system 800 is provided by a personal computer (PC), a tablet PC, a Set-Top Box (STB), a Personal Digital Assistant (PDA), a cellular telephone, a web appliance, a server, a network router, switch or bridge, or any device capable of executing a set of instructions (sequential or otherwise) that specify actions to be taken by that device. Further, the term “computer” shall include any collection of computers that individually or jointly execute a set (or multiple sets) of instructions to perform any one or more of the methods described herein.

In a further aspect, the computer system 800 includes a processing device 802, a volatile memory 804 (e.g., Random Access Memory (RAM)), a non-volatile memory 806 (e.g., Read-Only Memory (ROM) or Electrically-Erasable Programmable ROM (EEPROM)), and a data storage device 816, which communicate with each other via a bus 808.

In some embodiments, processing device 802 is provided by one or more processors such as a general purpose processor (such as, for example, a Complex Instruction Set Computing (CISC) microprocessor, a Reduced Instruction Set Computing (RISC) microprocessor, a Very Long Instruction Word (VLIW) microprocessor, a microprocessor implementing other types of instruction sets, or a microprocessor implementing a combination of types of instruction sets) or a specialized processor (such as, for example, an Application Specific Integrated Circuit (ASIC), a Field Programmable Gate Array (FPGA), a Digital Signal Processor (DSP), or a network processor).

In some embodiments, computer system 800 further includes a network interface device 822 (e.g., coupled to network 874). In some embodiments, computer system 800 also includes a video display unit 810 (e.g., an LCD), an alphanumeric input device 812 (e.g., a keyboard), a cursor control device 814 (e.g., a mouse), and a signal generation device 820.

In some implementations, data storage device 816 includes a non-transitory computer-readable storage medium 824 on which store instructions 826 encoding any one or more of the methods or functions described herein. For example, the instructions 826 can include instructions for controlling the movement of the stage and/or exposure units of a digital lithography system, which, when executed, can implement the methods for performing exposure unit boundary smoothing described herein.

In some embodiments, instructions 826 also reside, completely or partially, within volatile memory 804 and/or within processing device 802 during execution thereof by computer system 800, hence, in some embodiments, volatile memory 804 and processing device 802 also constitute machine-readable storage media.

While computer-readable storage medium 824 is shown in the illustrative examples as a single medium, the term “computer-readable storage medium” shall include a single medium or multiple media (e.g., a centralized or distributed database, and/or associated caches and servers) that store the one or more sets of executable instructions. The term “computer-readable storage medium” shall also include any tangible medium that is capable of storing or encoding a set of instructions for execution by a computer that cause the computer to perform any one or more of the methods described herein. The term “computer-readable storage medium” shall include, but not be limited to, solid-state memories, optical media, and magnetic media.

In some embodiments, the methods, components, and features described herein are implemented by discrete hardware components or are integrated in the functionality of other hardware components such as ASICS, FPGAs, DSPs or similar devices. In some embodiments, the methods, components, and features are implemented by firmware modules or functional circuitry within hardware devices. In some embodiments, the methods, components, and features are implemented in any combination of hardware devices and computer program components, or in computer programs.

Unless specifically stated otherwise, terms such as “receiving,” “initiating,” “performing,” or the like, refer to actions and processes performed or implemented by computer systems that manipulates and transforms data represented as physical (electronic) quantities within the computer system registers and memories into other data similarly represented as physical quantities within the computer system memories or registers or other such information storage, transmission or display devices. In some embodiments, the terms “first,” “second,” “third,” “fourth,” etc. as used herein are meant as labels to distinguish among different elements and do not have an ordinal meaning according to their numerical designation.

Examples described herein also relate to an apparatus for performing the methods described herein. In some embodiments, this apparatus is specially constructed for performing the methods described herein, or includes a general purpose computer system selectively programmed by a computer program stored in the computer system. Such a computer program is stored in a computer-readable tangible storage medium.

The methods and illustrative examples described herein are not inherently related to any particular computer or other apparatus. In some embodiments, various general purpose systems are used in accordance with the teachings described herein. In some embodiments, a more specialized apparatus is constructed to perform methods described herein and/or each of their individual functions, routines, subroutines, or operations. Examples of the structure for a variety of these systems are set forth in the description above.

The preceding description sets forth numerous specific details such as examples of specific systems, components, methods, and so forth, in order to provide a good understanding of several embodiments of the present invention. It will be apparent to one skilled in the art, however, that at least some embodiments of the present invention may be practiced without these specific details. In other instances, well-known components or methods are not described in detail or are presented in simple block diagram format in order to avoid unnecessarily obscuring the present invention. Thus, the specific details set forth are merely exemplary. Particular implementations may vary from these exemplary details and still be contemplated to be within the scope of the present invention.

Reference throughout this specification to “one embodiment” or “an embodiment” means that a particular feature, structure, or characteristic described in connection with the embodiment is included in at least one embodiment. Thus, the appearances of the phrase “in one embodiment” or “in an embodiment” in various places throughout this specification are not necessarily all referring to the same embodiment. In addition, the term “or” is intended to mean an inclusive “or” rather than an exclusive “or.” When the term “about” or “approximately” is used herein, this is intended to mean that the nominal value presented is precise within ±10%.

Although the operations of the methods herein are shown and described in a particular order, the order of the operations of each method may be altered so that certain operations may be performed in an inverse order or so that certain operation may be performed, at least in part, concurrently with other operations. In another embodiment, instructions or sub-operations of distinct operations may be in an intermittent and/or alternating manner.

It is to be understood that the above description is intended to be illustrative, and not restrictive. Many other implementation examples will be apparent to those of skill in the art upon reading and understanding the above description. Although the present disclosure describes specific examples, it will be recognized that the systems and methods of the present disclosure are not limited to the examples described herein, but may be practiced with modifications within the scope of the appended claims. Accordingly, the specification and drawings are to be regarded in an illustrative sense rather than a restrictive sense. The scope of the present disclosure should, therefore, be determined with reference to the appended claims, along with the full scope of equivalents to which such claims are entitled.

What is claimed is:

1. A system comprising:
a memory; and
at least one processing device, operatively coupled to the memory, to perform operations comprising:
initiating a digital lithography process to use a digital lithography system to pattern a substrate;
controlling an area ratio in a first direction with respect to a first pair of adjacent exposure units of the digital lithography system; and
controlling a dose ratio in a second direction perpendicular to the first direction with respect to a second pair of adjacent exposure units of the digital lithography system.

2. The system of claim 1, wherein the first direction is a scan direction.

3. The system of claim 1, wherein:
the first pair of adjacent exposure units comprises a first exposure unit attached to a first bridge and a second exposure unit attached to a second bridge adjacent to the first bridge; and
the second pair of adjacent exposure units comprises a third exposure unit and a fourth exposure unit each attached to a third bridge.

4. The system of claim 3, wherein the area ratio defines a first amount of area that the first exposure unit is assigned to scan and a second amount of area that the second exposure unit is assigned to scan based on a position relative to the substrate along the first direction.

5. The system of claim 3, wherein the dose ratio defines a first target dose assigned to the third exposure unit and a second target dose assigned to the fourth exposure unit based on a position relative to the substrate along the second direction.

6. The system of claim 3, wherein the first exposure unit is the third exposure unit.

7. The system of claim 1, wherein the area ratio and the dose ratio are controlled to smooth boundaries between respective exposure units of the digital lithography system during the digital lithography process.

8. A method comprising:
initiating, by at least one processing device, a digital lithography process to use a digital lithography system to pattern a substrate;
controlling, by the at least one processing device, an area ratio in a first direction with respect to a first pair of adjacent exposure units of the digital lithography system; and
controlling, by the at least one processing device, a dose ratio in a second direction perpendicular to the first direction with respect to a second pair of adjacent exposure units of the digital lithography system.

9. The method of claim 8, wherein the first direction is a scan direction.

10. The method of claim 8, wherein:
the first pair of adjacent exposure units comprises a first exposure unit attached to a first bridge and a second exposure unit attached to a second bridge adjacent to the first bridge; and
the second pair of adjacent exposure units comprises a third exposure unit and a fourth exposure unit each attached to a third bridge.

11. The method of claim 10, wherein the area ratio defines a first amount of area that the first exposure unit is assigned to scan and a second amount of area that the second exposure unit is assigned to scan based on a position relative to the substrate along the first direction.

12. The method of claim 10, wherein the dose ratio defines a first target dose assigned to the third exposure unit and a second target dose assigned to the fourth exposure unit based on a position relative to the substrate along the second direction.

13. The method of claim 10, wherein the first exposure unit is the third exposure unit.

14. The method of claim 8, wherein the area ratio and the dose ratio are controlled to smooth boundaries between respective exposure units of the digital lithography system during the digital lithography process.

15. A system comprising:
a stage associated with a plurality of scan regions;
a plurality of exposure units located above the stage, wherein the plurality of exposure units comprises a first pair of adjacent exposure units and a second pair of adjacent exposure units;
at least one processing device, operatively coupled to a memory, to perform operations comprising:
initiating a digital lithography process to pattern a substrate disposed on the stage;
controlling an area ratio in a first direction with respect to the first pair of adjacent exposure units; and
controlling a dose ratio in a second direction perpendicular to the first direction with respect to the second pair of adjacent exposure units.

16. The system of claim 15, wherein the first direction is a scan direction.

17. The system of claim 15, wherein:
the first pair of adjacent exposure units comprises a first exposure unit attached to a first bridge and a second exposure unit attached to a second bridge adjacent to the first bridge; and
the second pair of adjacent exposure units comprises a third exposure unit and a fourth exposure unit each attached to a third bridge.

18. The system of claim 17, wherein the area ratio defines a first amount of area that the first exposure unit is assigned to scan and a second amount of area that the second exposure unit is assigned to scan based on a position relative to the substrate along the first direction.

19. The system of claim 17, wherein the dose ratio defines a first target dose assigned to the third exposure unit and a second target dose assigned to the fourth exposure unit based on a position relative to the substrate along the second direction.

20. The system of claim 17, wherein the first exposure unit is the third exposure unit.
